(19) United States
(12) Patent Application Publication
(10) Pub. No.: US 2026/0194581 A1
(43) Pub. Date: Jul. 9, 2026

(54) APPARATUS AND METHOD OF GENERATING LFP BATTERY MODEL

(71) Applicant: Samsung SDI Co., Ltd., Yongin-si (KR)

(72) Inventor: Hwa-Su Kim, Yongin-si (KR)

(73) Assignee: Samsung SDI Co., Ltd., Yongin-si (KR)

(21) Appl. No.: 19/434,814

(22) Filed: Dec. 29, 2025

(30) Foreign Application Priority Data
Jan. 9, 2025 (KR) 10-2025-0003704

(51) Int. Cl. G01R 31/367; G01R 31/392; H01M 4/02; H01M 4/58; H01M 10/0525; H02J 7/84

(52) U.S. Cl. CPC G01R 31/367; G01R 31/392; H01M 4/5825; H02J 7/84; H01M 2004/028; H01M 10/0525

(57) ABSTRACT

Disclosed are an apparatus and a method of generating a lithium iron phosphate (LiFePO₄, LFP) battery model. The apparatus includes: a lithium state recorder configured to record a state of lithium (Li) in a positive electrode active material of an LFP battery according to charging or discharging of the LFP battery; and a battery model generator configured to generate a battery model of the LFP battery based on the recorded state of the Li in the positive electrode active material. The battery model generator generates a battery model by modeling the LFP battery using a capacitor and a plurality of resistors including an additional resistance component generated based on the state of the Li in the positive electrode active material.

### CROSS-REFERENCE TO RELATED APPLICATIONS

This present application claims priority to and the benefit under 35 U.S.C. § 119(a)-(d) of Korean Patent Application No. 10-2025-0003704, filed on Jan. 9, 2025, in the Korean Intellectual Property Office, the entire disclosure of which is incorporated herein by reference.

### FIELD

The present disclosure relates to an apparatus and a method of generating a lithium iron phosphate (LiFePO₄, LFP) battery model, and more particularly, to an apparatus and a method of generating an LFP battery model, which record a state of lithium (Li) in a positive electrode active material of an LFP battery according to charging or discharging of the LFP battery, and generate a battery model of the LFP battery based on the recorded state of the Li in the positive electrode active material.

### BACKGROUND

Unlike primary batteries that are not designed to be charged, secondary batteries are designed to be discharged and recharged. Low-capacity secondary batteries are used in small portable electronic devices, such as smart phones, feature phones, notebook computers, digital cameras, and camcorders, while large-capacity secondary batteries are widely used as power sources for driving motors, such as of hybrid vehicles or electric vehicles, and for power storage. The secondary battery includes an electrode assembly consisting of a positive electrode and a negative electrode, a case that accommodates the electrode assembly, a terminal part connected to the electrode assembly, etc.

Lithium-ion batteries may be classified according to a material constituting a positive electrode material. Based on the positive electrode material, the lithium-ion batteries are classified into a ternary battery and a quaternary battery, which are formed of a lithium cobalt oxide (LCO) positive electrode material, and a lithium iron phosphate (LiFePO₄, LFP) battery, which is formed of an LFP positive electrode material using iron phosphate in place of cobalt. The LFP battery uses iron phosphate, which is less expensive than cobalt, thereby reducing the cost of raw materials used for battery manufacturing, and has an olivine structure, which is formed in a hexahedral shape, among various types of positive electrode material structures, thereby being stable. Accordingly, the LFP battery has advantages in that a possibility of accidents caused by overcharging or overdischarging is relatively low, and degradation of battery cells is reduced, thereby resulting in a relatively long battery lifespan.

A battery pack including a plurality of battery cells may include a battery management system (BMS) configured to manage the plurality of battery cells, for example, by monitoring voltage, current, and temperature of the plurality of battery cells included in the battery pack.

Development of a battery model is required in order to implement an algorithm that determines battery parameters such as a state of charge (SOC), a state of health (SOH), and the like, which are applied to the BMS. However, in a conventional equivalent circuit model (ECM) method used for ternary batteries, a unique characteristic of LFP batteries, in which internal resistance varies depending on a charging or discharging path, cannot be reflected in any way. Accordingly, the conventional ECM method is problematic in that errors in the battery model increase, and as a result, errors in the SOC and SOH also increase.

The herein information disclosed in this Background section is for enhancement of understanding of the background of the present disclosure, and therefore, it may contain information that does not constitute related (or prior) art.

### SUMMARY

Embodiments of the present disclosure are directed to providing an apparatus and a method of generating a lithium iron phosphate (LiFePO₄, LFP) battery model, which record a state of lithium (Li) in a positive electrode active material of an LFP battery according to charging or discharging of the LFP battery, and generate a battery model of the LFP battery based on the recorded state of the Li in the positive electrode active material.

However, the technical problem to be solved by the present disclosure is not limited to the above problem, and other problems not mentioned herein, and aspects and features of the present disclosure that would address such problems, will be clearly understood by those skilled in the art from the description of the present disclosure herein.

An apparatus for generating a lithium iron phosphate (LiFePO₄, LFP) battery model according to embodiments of the present disclosure may include: a lithium state recorder configured to record a state of lithium (Li) in a positive electrode active material of an LFP battery according to charging or discharging of the LFP battery; and a battery model generator configured to generate a battery model of the LFP battery based on the recorded state of the Li in the positive electrode active material. The battery model generator may generate a battery model by modeling the LFP battery using a capacitor and a plurality of resistors including an additional resistance component generated based on the state of the Li in the positive electrode active material.

In embodiments, the Li state recorder may record a distribution state of the Li from a peripheral portion to a center in the positive electrode active material of the LFP battery, the distribution state varying depending on the charging or discharging of the LFP battery.

In embodiments, the battery generator may generate the battery model of the LFP battery in a form in which the additional resistance component generated based on the state of the Li in the positive electrode active material is included in an equivalent circuit model (ECM).

In embodiments, the battery model generator may generate the battery model of the LFP battery by classifying, when charging the LFP battery, the state of the Li distribution into a first circumstance in which the Li is not distributed in the peripheral portion of the positive electrode active material of the LFP battery, and a second circumstance in which the Li is distributed in the peripheral portion of the positive electrode active material of the LFP battery.

In embodiments, the battery model generator may generate the battery model of the LFP battery by classifying, when discharging the LFP battery, the state of the Li distribution into a third circumstance in which the Li is not distributed in the peripheral portion of the positive electrode active material of the LFP battery, and a fourth circumstance in which the Li is distributed in the peripheral portion of the positive electrode active material of the LFP battery.

In embodiments, when the additional resistance component measured in a circumstance where a path-dependent effect of the positive electrode active material is greatest is designated as R_{ovp_max}, and a correction value reflecting the state of the Li in the positive electrode active material is designated as Kₒᵥₚ, an additional resistance component Rove generated based on the state of the Li in the positive electrode active material may be determined by a following equation:

$${R}_{ovp} = {K}_{ovp} * {R}_{ovp \_ max} .$$

In embodiments, when, during charging of the LFP battery, at a moment when the charging begins, a starting point of a rich phase of the Li from the peripheral portion in the positive electrode active material of the LFP battery is designated as SP_{rich}, a first ending point of the rich phase is designated as EP_{rich}, a first ending point of a poor phase is designated as EPₚₒₒᵣ, and EP_{rich} is smaller than EPₚₒₒᵣ, a correction value K_{OVP} reflecting the state of the Li in the positive electrode active material may be determined by a following equation:

$${K}_{ovp} = \frac{{SP}_{rich}}{{EP}_{rich}} .$$

In embodiments, in a circumstance where the EP_{rich} is greater than or equal to EPₚₒₒᵣ, the correction value K_{OVP} reflecting the state of the Li in the positive electrode active material may be set to 1.

In embodiments, when, during discharging of the LFP battery, at a moment when the discharging begins, a first ending point of a rich phase of the Li from the peripheral portion in the positive electrode active material of the LFP battery is designated as EP_{rich}, a first starting point of a poor phase is designated as SPₚₒₒᵣ, a first ending point of the poor phase is designated as EPₚₒₒᵣ, and EPₚₒₒᵣ is smaller than EP_{rich}, a correction value Kₒᵥₚ reflecting the state of the Li in the positive electrode active material may be determined by a following equation:

$${K}_{ovp} = \frac{{SP}_{poor}}{{EP}_{poor}} .$$

In embodiments, in a circumstance where the EPₚₒₒᵣ is greater than or equal to EP_{rich}, the correction value Kₒᵥₚ reflecting the state of the Li in the positive electrode active material may be set to 1.

A method of generating a lithium iron phosphate (LiFePO₄, LFP) battery model according to embodiments of the present disclosure may include: a lithium state recording operation of recording, by a lithium state recorder, a state of lithium (Li) in a positive electrode active material of an LFP battery according to charging or discharging of the LFP battery; and a battery model generation operation of generating, by a battery model generator, a battery model of the LFP battery based on the recorded state of the Li in the positive electrode active material. The battery model generation operation may include generating the battery model by modeling the LFP battery using a capacitor and a plurality of resistors including an additional resistance component generated based on the state of the Li in the positive electrode active material.

In embodiments, the Li state recording operation may include recording a distribution state of the Li from a peripheral portion to a center in the positive electrode active material of the LFP battery, the distribution state varying depending on the charging or discharging of the LFP battery.

In embodiments, the battery model generation operation may include generating the battery model of the LFP battery in a form in which the additional resistance component generated based on the state of the Li in the positive electrode active material is included in an equivalent circuit model (ECM).

In embodiments, the battery model generation operation may include generating the battery model of the LFP battery by classifying, when charging the LFP battery, the state of the Li distribution into a first circumstance in which the Li is not distributed in the peripheral portion of the positive electrode active material of the LFP battery, and a second circumstance in which the Li is distributed in the peripheral portion of the positive electrode active material of the LFP battery.

In embodiments, the battery model generation operation may further include generating the battery model of the LFP battery by classifying, when discharging the LFP battery, the state of the Li distribution into a third circumstance in which the Li is not distributed in the peripheral portion of the positive electrode active material of the LFP battery, and a fourth circumstance in which the Li is distributed in the peripheral portion of the positive electrode active material of the LFP battery.

In embodiments, the battery model generation operation may include determining an additional resistance component R_{OVP} generated based on the state of the Li in the positive electrode active material by a following equation, when the additional resistance component measured in a circumstance where a path-dependent effect of the positive electrode active material is greatest is designated as R_{ovp_max}, and a correction value reflecting the state of the Li in the positive electrode active material is designated as Kₒᵥₚ:

$${R}_{ovp} = {K}_{ovp} * {R}_{ovp \_ max} .$$

In embodiments, the battery model generation operation may further include determining the correction value K_{OVP} reflecting the state of the Li in the positive electrode active material by a following equation when, during charging of the LFP battery, at a moment when the charging begins, a starting point of a rich phase of the Li from the peripheral portion in the positive electrode active material of the LFP battery is designated as SP_{rich}, a first ending point of the rich phase is designated as EP_{rich}, a first ending point of a poor phase is designated as EPₚₒₒᵣ, and EP_{rich} is smaller than EPₚₒₒᵣ:

$${K}_{ovp} = \frac{{SP}_{rich}}{{EP}_{rich}} .$$

In embodiment, the battery model generation operation may further include setting the correction value K_{OVP} reflecting the state of the Li in the positive electrode active material to 1 in a circumstance where the EP_{rich} is greater than or equal to EPₚₒₒᵣ.

In embodiments, the battery model generation operation may further include determining a correction value K_{OVP} reflecting the state of the Li in the positive electrode active material by a following equation when, during discharging of the LFP battery, at a moment when the discharging begins, a first ending point of a rich phase of the Li from the peripheral portion in the positive electrode active material of the LFP battery is designated as EP_{rich}, a first starting point of a poor phase is designated as SPₚₒₒᵣ, a first ending point of the poor phase is designated as EPₚₒₒᵣ, and EPₚₒₒᵣ is smaller than EP_{rich}:

$${K}_{ovp} = \frac{{SP}_{poor}}{{EP}_{poor}} .$$

In embodiments, the battery model generation operation may further include setting the correction value K_{OVP} reflecting the state of the Li in the positive electrode active material to 1 in a circumstance where the EPₚₒₒᵣ is greater than or equal to EP_{rich}.

According to embodiments of the present disclosure, a state of Li in a positive electrode active material of a Li iron phosphate (LiFePO₄, LFP) battery according to charging or discharging of the LFP battery is recorded, and a battery model of the LFP battery is generated based on the recorded state of Li in the positive electrode active material. Accordingly, it is possible to record the state of Li in the positive electrode active material that changes depending on the history of a previous charging or discharging path, define variation in internal resistance depending on a current internal state of the positive electrode that reflects the history of the previous charging or discharging path, and ultimately apply the defined variation to the battery model.

According to embodiments of the present disclosure, a battery model that reflects the internal state of the positive electrode active material that varies depending on the history of the previous charging or discharging path is generated. Hence, errors in the battery model may be reduced, and the accuracy may be improved, thereby reducing errors in a state of charge (SOC) and a state of health (SOH) of the battery, which are calculated by a battery management system (BMS).

However, aspects and features of the present disclosure are not limited to those described herein, and other aspects and features not mentioned will be clearly understood by a person skilled in the art from the detailed description, described herein.

### BRIEF DESCRIPTION OF THE DRAWINGS

The following drawings attached to this specification illustrate preferred embodiments of the present disclosure, and help to further understand the technical spirit of the present disclosure along with the aforementioned contents of the disclosure. Accordingly, the present disclosure should not be construed as being limited to only contents described in such drawings:

FIG. 1 is a schematic view illustrating a cylindrical lithium secondary battery according to embodiments;

FIG. 2 is a schematic diagram illustrating a prismatic lithium secondary battery according to embodiments;

FIGS. 3 and 4 are schematic diagrams illustrating a pouch-type lithium secondary battery according to embodiments;

FIG. 5 illustrates a battery model implemented by a conventional equivalent circuit model (ECM) method;

FIG. 6 is a diagram illustrating an example of a resistance value varying depending on a charging path of a lithium iron phosphate (LFP) battery;

FIG. 7 is a diagram schematically illustrating an apparatus for generating an LFP battery model according to embodiments of the present disclosure;

FIG. 8 is a diagram for explaining a method by which a lithium state recorder of the LFP battery model generation apparatus according to embodiments of the present disclosure records a state of lithium in a positive electrode active material of the LFP battery;

FIG. 9 illustrates an example in which the lithium state recorder of the LFP battery model generation apparatus according to embodiments of the present disclosure records the state of lithium in the positive electrode active material of the LFP battery;

FIG. 10 is a diagram for explaining examples in which the lithium state recorder of the LFP battery model generation apparatus according to embodiments of the present disclosure records the state of lithium in the positive electrode active material of the LFP battery during charging of the LFP battery;

FIG. 11 is a diagram for explaining examples in which the lithium state recorder of the LFP battery model generation apparatus according to embodiments of the present disclosure records the state of lithium in the positive electrode active material of the LFP battery during discharging of the LFP battery;

FIG. 12 is a diagram illustrating an example of a battery model generated by a battery model generator of the LFP battery model generation apparatus according to embodiments of the present disclosure;

FIGS. 13A-13D are diagrams for explaining an additional resistance component of a battery model generated by the battery model generator of the LFP battery model generation apparatus according to embodiments of the present disclosure;

FIGS. 14 and 15 are diagrams for explaining examples in which the battery model generator of the LFP battery model generation apparatus according to embodiments of the present disclosure generates a battery model based on a state of lithium in the positive electrode active material of the LFP battery, the state being recorded by the lithium state recorder during charging of the LFP battery;

FIGS. 16 and 17 are diagrams for explaining examples in which the battery model generator of the LFP battery model generation apparatus according to embodiments of the present disclosure generates a battery model based on a state of lithium in the positive electrode active material of the LFP battery, the state being recorded by the lithium state recorder during discharging of the LFP battery; and

FIG. 18 is a flowchart for explaining a method of generating an LFP battery model according to embodiments of the present disclosure.

### DETAILED DESCRIPTION

Exemplary embodiments of the present disclosure will be described herein in detail with reference to the accompanying drawings. Prior to the description, it is noted that the terms or words used in this specification and claims should not be construed as being limited to common or dictionary meanings but instead should be understood to have meanings and concepts in agreement with the spirit of the present disclosure based on the principle that an inventor can define the concept of each term suitably in order to describe his/her own disclosure in the best way possible. Accordingly, since the embodiments described in this specification and the configurations illustrated in the drawings are only an example of the present disclosure and they do not cover all the technical ideas of the present disclosure, it should be understood that various changes and modifications may be made at the time of filing this application.

It will be further understood that the terms “comprises/includes” and/or “comprising/including” when used herein, specify the presence of stated features, integers, steps, operations, elements, components, and/or groups thereof, but do not preclude the presence or addition of one or more other features, integers, steps, operations, elements, components, and/or groups thereof.

In order to facilitate understanding of the present disclosure, the accompanying drawings are not drawn to scale and the dimensions of some components may be exaggerated. It should be noted that the same reference numerals are designated to the same components in different embodiments.

Reference to two compared elements, features, etc. as being “the same” means that they are “substantially the same”. Therefore, the phrase “substantially the same” may include a deviation that is considered low in the art, for example, a deviation of 5% or less. The uniformity of any parameter in a given region may mean that it is uniform from an average perspective.

Although the terms such as “first” and/or “second” are used to describe various components, these components are not limited by these terms, of course. These terms are only used to distinguish one component from another component. Thus, unless specifically stated to the contrary, a first component may be termed a second component without departing from the teachings of exemplary embodiments.

Throughout the specification, unless otherwise stated, each element may be singular or plural.

Arrangement of any component “above (or below)” or “on (or under)” a component may mean that any component is disposed in contact with the upper (or lower) surface of the component, as well as that other components may be interposed between the element and any element disposed on (or under) the element.

It will be understood that, when a component is referred to as being “connected”, “coupled”, or “joined” to another component, not only can it be directly “connected”, “coupled”, or “joined” to the other element, but also can it be indirectly “connected”, “coupled”, or “joined” to the other element with other elements interposed therebetween.

As used herein, the term “and/or” includes any and all combinations of one or more of the associate listed items. The use of “may” when describing embodiments of the present disclosure relates to “one or more embodiments of the present disclosure”. Expressions such as “at least one” and “one or more” preceding a list of elements modify the entire list of elements and do not modify the individual elements in the list.

Throughout the specification, when “A and/or B” is stated, it means A, B, or A and B, unless otherwise stated. In addition, when “C to D” is stated, it means C or more and D or less, unless specifically stated to the contrary.

When the phrase such as “at least one of A, B, and C”, “at least one of A, B, or C”, “at least one selected from the group of A, B, and C”, or “at least one selected from among A, B, and C” is used to designate a list of elements A, B, and C, the phrase may refer to any and all suitable combinations.

The term “use” may be considered synonymous with the term “utilize”. As used herein, the terms “substantially,” “about,” and similar terms are used as terms of approximation rather than as terms of degree, and are intended to account for inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Accordingly, a first element, component, region, layer, or section discussed herein may be termed a second element, component, region, layer, or section without departing from the teachings of exemplary embodiments.

For ease of explanation in describing the relationship of one element or feature to another element(s) or feature(s) as illustrated in the drawings, spatially relative terms such as “beneath”, “below”, “lower”, “above”, and “upper” may be used herein. It will be understood that spatially relative positions are intended to encompass different directions of the device in use or operation in addition to the direction depicted in the drawings. For example, if the device in the drawings is turned over, any element described as being “below” or “beneath” another element would then be oriented “above” or “over” another element. Therefore, the term “below” may encompass both upward and downward directions.

The terminology used herein is for the purpose of describing embodiments of the present disclosure and is not intended to limit the present disclosure.

The type of secondary battery includes a coin type, a cylindrical type, a prismatic type, and a pouch type. Prior to a description of embodiments of the present disclosure, first, cylindrical and prismatic secondary batteries are roughly described because the present disclosure may be basically applied to the cylindrical and prismatic secondary batteries.

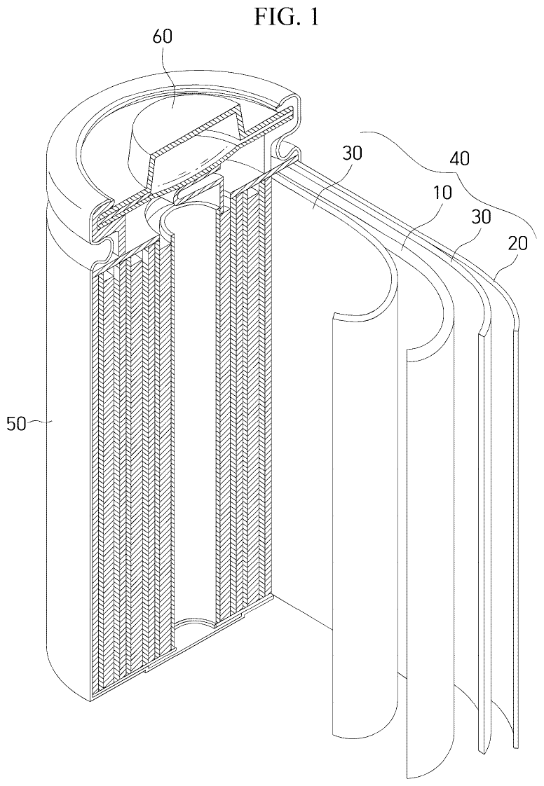

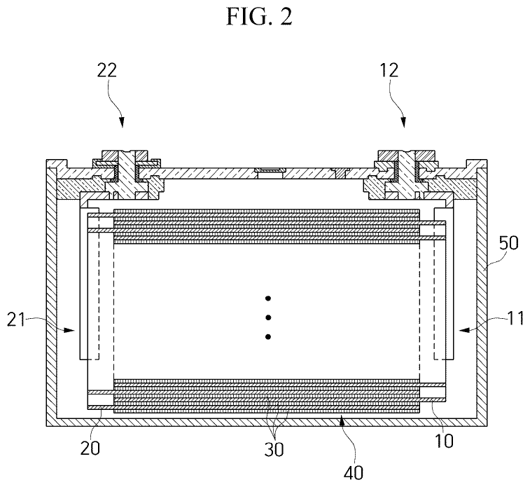

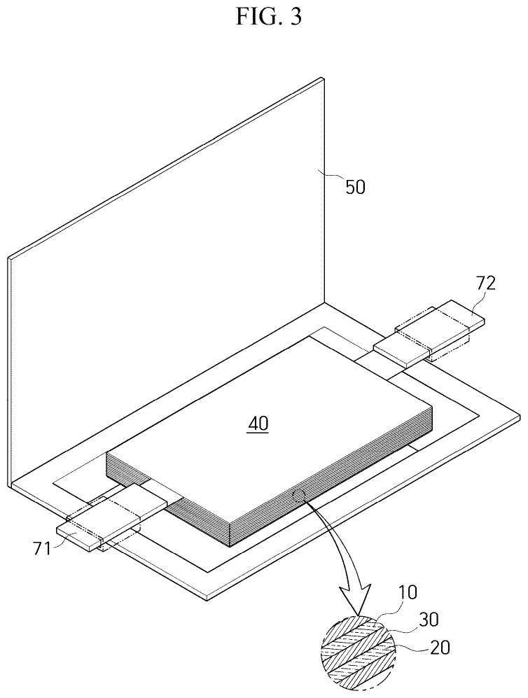

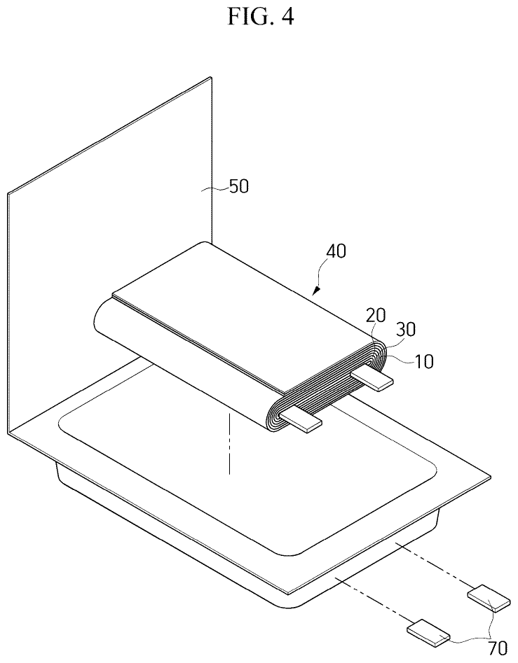

FIGS. 1 to 4 are schematic diagrams illustrating lithium secondary batteries according to implementation examples. FIG. 1 may illustrate a cylindrical lithium secondary battery. FIG. 2 may illustrate a prismatic type secondary battery. FIGS. 3 and 4 may illustrate a pouch type secondary battery. Referring to FIGS. 1 to 4, a lithium secondary battery 1 may include an electrode assembly 40 in which a separator 30 has been interposed between a first electrode plate 10 and a second electrode plate 20 and a case 50 in which the electrode assembly 40 has been embedded. The first electrode plate 10, the second electrode plate 20, and the separator 30 may be impregnated in an electrolyte (not illustrated). As illustrated in FIG. 1, the lithium secondary battery 1 may include a sealing member 60 that seals the case 50. Furthermore, in FIG. 2, the lithium secondary battery 1 may include a first electrode lead tab 11, a first electrode terminal 12, a second electrode lead tab 21, and a second electrode terminal 22. As illustrated in FIGS. 3 and 4, the lithium secondary battery 1 may include an electrode tab 70 that plays a role as an electrical passage for inducing a current formed in the electrode assembly 40 toward the outside, that is, a first electrode tab 71 and a second electrode tab 72.

The electrode assembly 40 may be formed by winding or stacking a stack body including the first electrode plate 10, the second electrode plate 20, and the separator 30 each of which is formed in a plate or film shape. In the circumstance of the winding stack body, the winding axis of the electrode assembly 40 may be parallel to the length direction of the case. Furthermore, the electrode assembly 40 may be the stack type not the winding type, but a shape of the electrode assembly 40 is not limited in embodiments of the present disclosure. The first electrode plate 10 of the electrode assembly 40 may play a role as a positive electrode, and the second electrode plate 20 thereof may play a role as a negative electrode, and vice versa.

The first electrode plate 10 may be formed by applying a first electrode active material, such as graphite or carbon, to a first electrode collector plate formed of metal foil, such as copper, a copper alloy, nickel, or a nickel alloy, and may include a first electrode tab (or a first uncoated part), that is, an area to which the first electrode active material has not been applied.

The second electrode plate 20 may be formed by applying a second electrode active material, such as transition metal oxide, to a material formed of metal foil, such as aluminum or an aluminum alloy, and may include a second electrode tab (or a second uncoated part), that is, an area to which the second electrode active material has not been applied.

The separator 30 may function to prevent a short-circuit between the first electrode plate 10 and the second electrode plate 20 while permitting a movement of lithium ions. The separator 30 may be composed of a polyethylene film, a polypropylene film, or a polyethylene-polypropylene film, for example.

The plurality of secondary batteries that has been described by taking FIGS. 1 to 4 as examples may be gathered to constitute a plurality of battery cells and accommodated in a battery case. A battery case according to embodiments of the present disclosure may include a support part that supports a hook after the hook and a hook hole are fastened, and can maintain the state in which the hook and the hook hole have been fastened because the breakaway of the hook attributable to the retreat of the hook can be prevented when an impact is applied to a battery pack. Hereinafter, a battery case according to embodiments of the present disclosure and a method of manufacturing the battery case are described with reference to drawings.

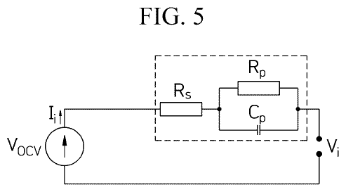

FIG. 5 illustrates a battery model implemented by a conventional equivalent circuit model (ECM) method.

Referring to FIG. 5, a battery model implemented by the conventional ECM method may be represented by a series resistor Rₛ for simulating a voltage drop in connection of a load and a voltage rise during charging, and a parallel resistor Rₚ and a parallel capacitor Cₚ for simulating a dynamic voltage response of a battery immediately after the voltage drop. In a conventional ternary battery, there is no path dependency, and thus resistance and capacitor values in a model do not need to include a previous charging or discharging history. Accordingly, a battery may be sufficiently simulated using a battery model based on the conventional ECM method.

However, an LFP battery may have a unique characteristic in that an internal resistance value varies depending on a charging or discharging path of the battery. For example, in the circumstance where a state of charge (SOC) of the LFP battery is decreased to 50% by discharging from 100%, and in another circumstance where the SOC is increased to 50% by charging from 0%, the LFP battery in both circumstances may have the same SOC value of 50%. However, since the charging and discharging paths to reach the SOC of 50% are different, a distribution of lithium (Li) ions in a positive electrode active material may become different, and difference in the distribution may cause internal resistance values in the two circumstances to vary, resulting in different internal resistance values.

Accordingly, in the circumstance of the LFP battery, if a battery model implemented by the conventional ECM method is used, there is a problem in that, when parameters of the series resistor Rₛ, the parallel resistor Rₚ, and the parallel capacitor Cₚ are set based on a specific charging or discharging path, all differences in internal resistance values caused by other charging or discharging paths appear as errors.

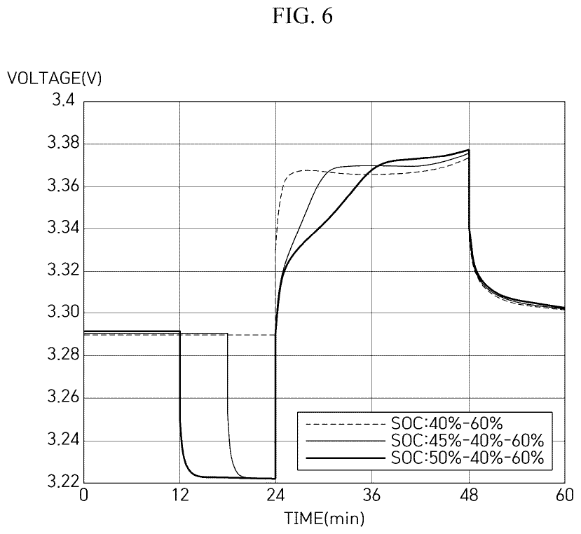

FIG. 6 is a diagram illustrating an example of the resistance value varying depending on the charging path of the LFP battery.

Referring to FIG. 6, a voltage variation graph over time is illustrated for the circumstance where the SOC increases from 40% to 60%, the circumstance where the SOC decreases from 45% to 40% and then increases to 60%, and the circumstance where the SOC decreases from 50% to 40% and then increases to 60%.

As illustrated in FIG. 6, in the circumstance where the SOC increases from 40% to 60%, the voltage increases with the highest gradient. In the circumstance where the SOC decreases from 45% to 40% and then increases to 60%, the gradient of voltage rise is slightly smaller than that in the former circumstance. In the circumstance where the SOC decreases from 50% to 40% and then increases to 60%, the voltage increases with the lowest gradient.

The reason for the foregoing is that differences in internal resistance values occur depending on a charging or discharging path of the LFP battery, and such differences result in variations in the voltage rise graph. Accordingly, the battery model implemented by the conventional ECM method of FIG. 5 is problematic in that even if parameters are set based on a graph corresponding to any charging or discharging path, errors occur in all other charging or discharging paths.

Accordingly, in the circumstance where an ECM model is intended to be applied to an LFP battery, parameters need to be supplemented so that the charging or discharging path of the LFP battery is reflected in the parameters. In accordance with an apparatus and a method of generating an LFP battery model according to embodiments of the present disclosure, internal resistance values that vary depending on charging and discharging paths may all be reflected in the battery model. Therefore, a battery model can be generated regardless of which charging or discharging path is followed among the three graphs in FIG. 6. As a result, errors in the battery model may be reduced, thereby improving accuracy.

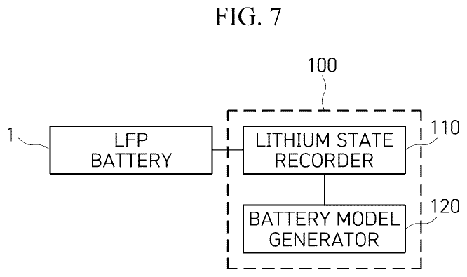

FIG. 7 is a diagram schematically illustrating an apparatus for generating an LFP battery model according to embodiments of the present disclosure.

Referring to FIG. 7, the LFP battery model generation apparatus 100 according to embodiments of the present disclosure may include a lithium state recorder 110 and a battery model generator 120. The LFP battery model generation apparatus 100 according to embodiments of the present disclosure may be included in a battery management system (BMS), and may generate a battery model of an LFP battery 1.

The lithium state recorder 110 may record a state of lithium in a positive electrode active material of the LFP battery 1 according to charging or discharging of the LFP battery 1.

The battery model generator 120 may generate the battery model of the LFP battery 1 based on the recorded state of lithium in a positive electrode active material. In embodiments, the battery model generator 120 may generate the battery model by modeling the LFP battery 1 using a plurality of capacitors and a plurality of resistors, including an additional resistance component generated based on the state of lithium in the positive electrode active material.

Hereinafter, with reference to the drawings, examples of specific methods will be described, in which the lithium state recorder 110 records the state of lithium in the positive electrode active material of the LFP battery 1, and the battery model generator 120 generates a battery model of the LFP battery 1 based on the recorded state of lithium in the positive electrode active material.

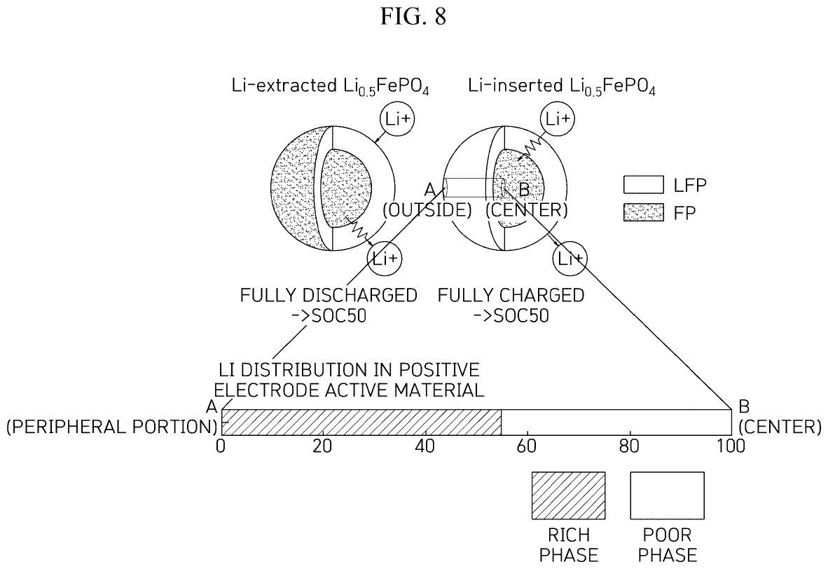

FIG. 8 is a diagram for explaining a method by which the lithium state recorder of the LFP battery model generation apparatus according to embodiments of the present disclosure records the state of lithium in the positive electrode active material of the LFP battery.

Referring to FIG. 8, the positive electrode active material of the LFP battery is illustrated. The left portion in the drawing illustrates the positive electrode active material in the circumstance where charging is performed from a fully discharged state, that is, an SOC of 0%, to an SOC of 50%. The right portion in the drawing illustrates the positive electrode active material in the circumstance where discharging is performed from a fully charged state, that is, an SOC of 100%, to an SOC of 50%.

As charging or discharging progresses, the positive electrode active material repeatedly transitions between a LiFePO₄ (LFP) state and a FePO₄ (FP) state, which may be represented by the following chemical formula.

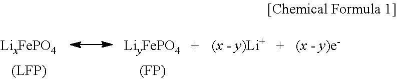

Due to a chemical reaction as represented by the above chemical formula, during charging from the fully discharged state as shown on the left portion of FIG. 8, Lit ions exit toward a negative electrode starting from a peripheral portion of the positive electrode active material. Here, a boundary between an outer FP region and an inner LFP region moves from the peripheral portion toward the center.

In addition, during discharging from the fully charged state as shown on the right portion of FIG. 8, Lit ions are pushed into a positive electrode starting from a peripheral portion of the positive electrode active material. In this circumstance, a boundary between an outer LFP region and an inner FP region moves from the peripheral portion toward the center.

The state of lithium in the positive electrode active material, that is, a change in the distribution of lithium, may be represented as a one-dimensional bar graph illustrating a region from the peripheral portion to the center of the positive electrode active material. For example, the circumstance of discharging from the fully charged state shown on the right portion of FIG. 8 will be described with reference to a bar graph in the lower portion of FIG. 8. When lithium flows in from the peripheral portion, the boundary between the outer LFP region and the inner FP region moves from the peripheral portion toward the center. As a result, a left region closer to the peripheral portion may become a rich phase in which lithium is sufficient, and a right region closer to the center may become a poor phase in which lithium is nearly absent.

Here, the description “lithium is distributed in the peripheral portion” may mean a state in which, when a positive electrode active material particle is modeled, lithium ions accumulate from a surface of the positive electrode active material particle, thus forming a layer adjacent to the surface of the particle. The aforementioned layer allows lithium adjacent to the surface of the particle to easily exit during charging, and makes it difficult for lithium to enter during discharging due to the lithium adjacent to the surface of the particle.

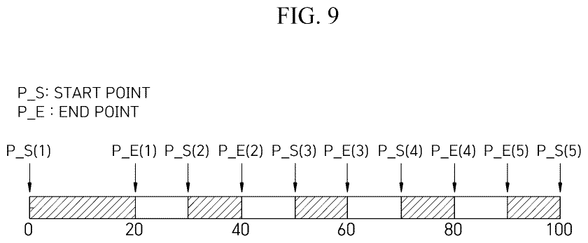

FIG. 9 illustrates an example in which the lithium state recorder of the LFP battery model generation apparatus according to embodiments of the present disclosure records the state of lithium in positive electrode active material of the LFP battery.

Referring to FIG. 9, an example of a bar graph is illustrated, in which the lithium state recorder of the LFP battery model generation apparatus according to embodiments of the present disclosure records the state of lithium in the positive electrode active material of the LFP battery by the method described in FIG. 8.

As described herein with reference to FIG. 8, during charging from the fully discharged state, when Lit ions exit toward the negative electrode starting from the peripheral portion of the positive electrode active material, the boundary between the outer FP region and the inner LFP region moves from the peripheral portion toward the center. During discharging from the fully charged state, when Lit ions are pushed into the positive electrode starting from the peripheral portion of the positive electrode active material, the boundary between the outer LFP region and the inner FP region moves from the peripheral portion toward the center.

The foregoing charging and discharging processes may be recorded through the SOC of the battery. In this circumstance, a starting position of lithium ions may be expressed as a point start P_S, and an ending position of lithium ions may be expressed as a point end P_E. According to such charging and discharging history, an internal layer may be formed, and P_S and P_E may be represented as multiple arrays in order to express such layer information, as illustrated in FIG. 9.

The internal state may be simulated only in a region (corresponding to an SOC range of approximately 10% to 90%) where a rich (beta) phase and a poor (alpha) phase coexist in the positive electrode active material and the voltage remains flat. However, for convenience, the same simulation method may be applied to other regions, and thereafter, when applied to the model, the corresponding algorithm may be reflected only in the region of the positive electrode active material where the voltage remains flat.

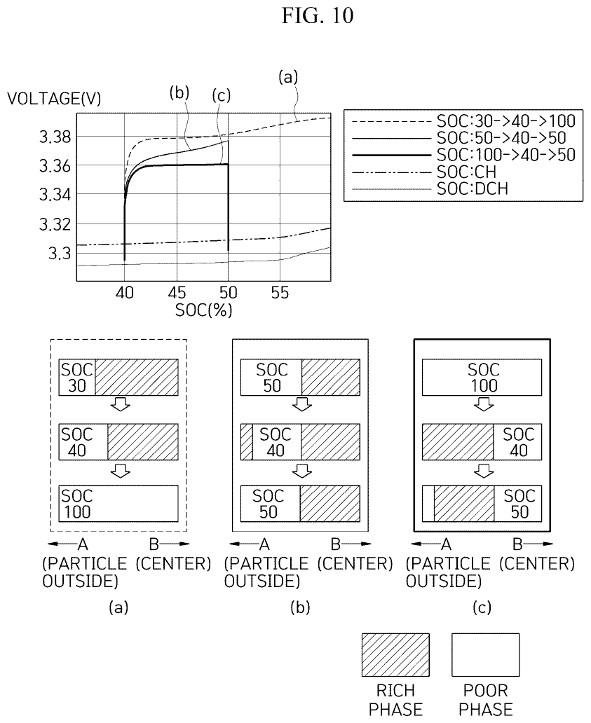

FIG. 10 is a diagram for explaining examples in which the lithium state recorder of the LFP battery model generation apparatus according to embodiments of the present disclosure records the state of lithium in the positive electrode active material of the LFP battery during charging of the LFP battery.

Referring to FIG. 10, a state of lithium in a positive electrode active material of the LFP battery during charging is illustrated. During charging of the LFP battery, Lit ions exit through the peripheral portion of the positive electrode active material and move toward the negative electrode, and thus a boundary between the FP region and the LFP region shifts toward the center.

In FIG. 10, in the circumstance of (a), as shown on the right portion in the drawing, charging may be performed from an SOC of 30% to 40%, and the peripheral portion may be in a poor phase. Accordingly, when charging is performed up to an SOC of 100%, the Lit ions located inside are required to pass through the portion in the poor phase to move outward, resulting in high internal resistance.

In the circumstance of (c), as shown on the right portion in the drawing, discharging may be performed from the SOC of 100% to 40%, and a rich phase may remain in the peripheral portion. Accordingly, when charging is performed up to an SOC of 50%, the Li+ ions may directly move outward from the peripheral portion, resulting in low internal resistance.

In the circumstance of (b), as shown on the right portion in the drawing, discharging may be performed from the SOC of 50% to 40%, and although a rich phase remains in the peripheral portion, the amount thereof may be smaller than that in the circumstance of (c). Accordingly, when charging is performed up to the SOC of 50%, the internal resistance may gradually increase until the Lit ions are completely extracted from a most peripheral portion in the rich phase. Here, the internal resistance may be related to the thickness of the most peripheral portion in the rich phase.

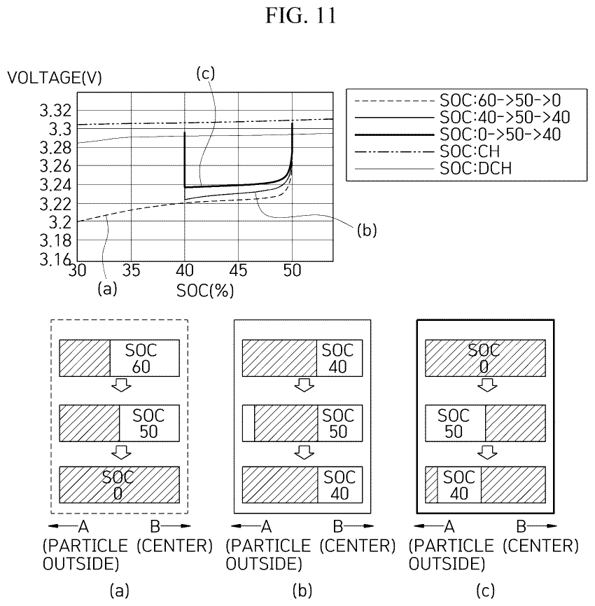

FIG. 11 is a diagram for explaining examples in which the lithium state recorder of the LFP battery model generation apparatus according to embodiments of the present disclosure records the state of lithium in the positive electrode active material of the LFP battery during discharging of the LFP battery.

Referring to FIG. 11, the state of lithium in the positive electrode active material of the LFP battery during discharging of the LFP battery is illustrated. During discharging of the LFP battery, Lit ions enter through the peripheral portion of the positive electrode active material from the negative electrode; therefore, the boundary between the LFP region and the FP region moves toward the center.

In FIG. 11, in the circumstance of (a), as shown on the right portion in the drawing, discharging may be performed from an SOC of 60% to 50%, and the peripheral portion may be in a rich phase. Accordingly, when discharging is performed down to an SOC of 0%, the Lit ions located in the peripheral portion are required to pass through the portion in the rich phase to enter, resulting in high internal resistance.

In the circumstance of (c), as illustrated on the right portion in the drawing, charging may be performed from the SOC of 0% to 50%, and a poor phase may be present in the peripheral portion. Accordingly, when discharging is performed down to an SOC of 40%, Lit ions may directly enter from the peripheral portion and directly settle in place, resulting in low internal resistance.

In the circumstance of (b), as illustrated on the right portion of the drawing, charging may be performed from the SOC of 40% to 50%, and although a poor phase remains in the peripheral portion, the amount thereof may be smaller than that in the circumstance of (c). Accordingly, when discharging is performed down to the SOC of 40%, internal resistance may gradually increase until Lit ions fully occupy the most peripheral portion in the poor phase. Here, the internal resistance may be related to the thickness of the most peripheral portion in the poor phase.

As described herein, the lithium state recorder 110 of the LFP battery model generation apparatus 100 according to embodiments of the present disclosure may record the state of lithium in the positive electrode active material of the LFP battery 1 by the method described with reference to FIGS. 8 to 11.

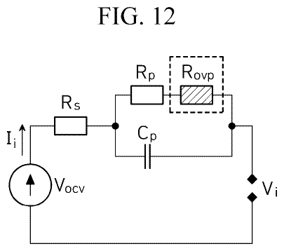

FIG. 12 is a diagram illustrating an example of a battery model generated by a battery model generator of the LFP battery model generation apparatus according to embodiments of the present disclosure.

Referring to FIG. 12, the battery model generator 110 of the LFP battery model generation apparatus 100 according to embodiments of the present disclosure may generate a battery model of the LFP battery in a form in which an additional resistance component R_{OVP} generated based on the state of the lithium in the positive electrode active material is included in an equivalent circuit model ECM. In other words, the series resistor Rₛ, the parallel resistor Rₚ, and the parallel capacitor Cₚ may remain without modification in the battery model generated by the conventional ECM method, and the additional resistance component R_{OVP} may be added.

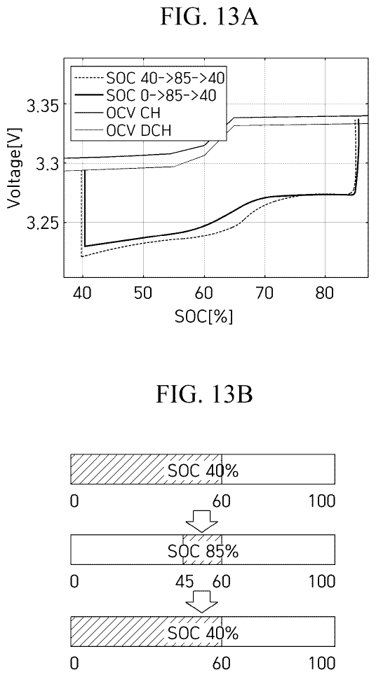

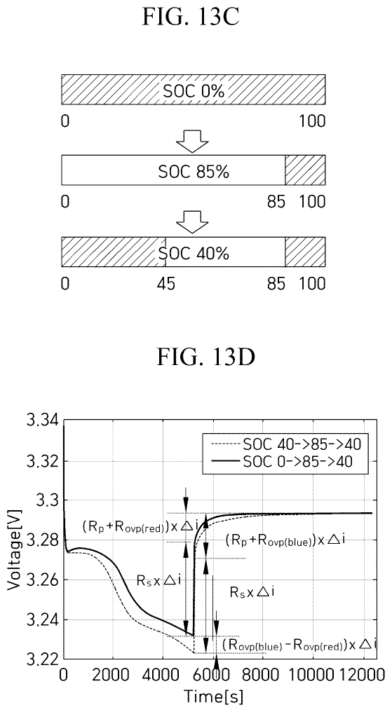

Hereinafter, with reference to FIGS. 13A-13D, the additional resistance component R_{OVP} of the battery model generated by the battery model generator 110 of the LFP battery model generation apparatus 100 according to embodiment [symbol] of the present disclosure will be described.

FIGS. 13A-13D are diagrams for explaining the additional resistance component of the battery model generated by the battery model generator of the LFP battery model generation apparatus according to embodiments of the present disclosure.

Referring to FIGS. 13A-13D, as an example of discharging, a comparison is made between the circumstance in which the SOC changes from 40% to 85% and then to 40%, and the circumstance in which the SOC changes from 0% to 85% and then to 40%.

In FIG. 13A, a voltage variation according to the Soc is shown. As illustrated in (a), it can be confirmed that a dotted-line graph representing the circumstance in which the SOC changes from 40% to 85% and then to 40% is higher in resistance than a solid-line graph representing the circumstance in which the SOC changes from 0% to 85% and then to 40%.

In detail, as shown in FIG. 13B, which illustrates the distribution of lithium ions in the positive electrode active material in the circumstance where the SOC changes from 40% to 85% and then to 40%, lithium ions may still remain in an intermediate region when the SOC changes from 40% to 85%, resulting in the presence of internal resistance. In contrast, as shown in FIG. 13C, which illustrates the distribution of lithium ions in the positive electrode active material in the circumstance where the SOC changes from 0% to 85% and then to 40%, when the SOC changes from 0% to 85%, lithium ions that have been in the peripheral portion may be fully extracted, thereby resulting in lower internal resistance compared to the circumstance shown in (b).

FIG. 13D illustrates voltage variation over time. Here, when the additional resistance component generated due to the distribution of lithium ions in the positive electrode active material is designated as R_{OVP}, a difference between the two resistances at SOC 40% when the discharging is terminated may correspond to R_{OVP (blue)}−R_{OVP (red)}. When entering a rest mode after reaching the SOC of 40%, in the battery model based on the ECM method, an initial voltage drop may occur due to the influence of the series resistor Rs, and thereafter, relaxation may proceed by an amount corresponding to a combination of the parallel resistor Rₚ and the additional resistance component R_{OVP}. Here, the additional resistance component R_{OVP} may maintain a final value of the discharging and be directly reflected in a discharge graph.

The herein-mentioned additional resistance component R_{OVP} may be reflected in the ECM in an added form, as illustrated in FIG. 12.

A method of determining the additional resistance component R_{OVP} of the battery model generated by the battery model generator 110 of the LFP battery model generation apparatus 100 according to embodiments of the present disclosure is as follows.

When the additional resistance component measured in the circumstance where the path-dependent effect of the positive electrode active material is greatest is designated as R_{ovp_max}, and a correction value reflecting the state of lithium in the positive electrode active material is designated as Kₒᵥₚ, an additional resistance component R_{OVP} generated based on the state of lithium in the positive electrode active material may be calculated by the following equation.

$${R}_{ovp} = {K}_{ovp} * {R}_{ovp \_ max} \qquad [ Equation 1 ]$$

Here, the circumstance in which the path-dependent effect is greatest may correspond to the circumstance in which the internal resistance is highest due to the state of lithium in the positive electrode active material. For example, during charging, when the peripheral portion is in a poor phase, lithium ions located in an inner portion are required to pass through the portion in the poor phase to exit, resulting in relatively high internal resistance. Alternatively, during discharging, when the peripheral portion is in a rich phase, lithium ions located in the peripheral region are required to pass through the portion in the rich phase to move inward, resulting in relatively high internal resistance. In Equation 1 above, 0≤K_{OVP}≤1, and the circumstance in which the path-dependent effect is greatest may correspond to a state of K_{OVP}=1.

Parameters of the series resistor Rₛ, the parallel resistor Rₚ, and the parallel capacitor Cₚ, excluding the additional resistance component Rove of the battery model generated by the battery model generator 110, may be obtained by performing calibration based on values measured in a section where K_{OVP} is 0. In the battery model generated by the battery model generator 110, R_{ovp_max} may be obtained by measuring parameters in a section where K_{OVP} is 1 and calculating a value of R_{ovp_max} to be added to the existing parameters of the series resistor Rₛ, the parallel resistor Rₚ, and the parallel capacitor Cₚ.

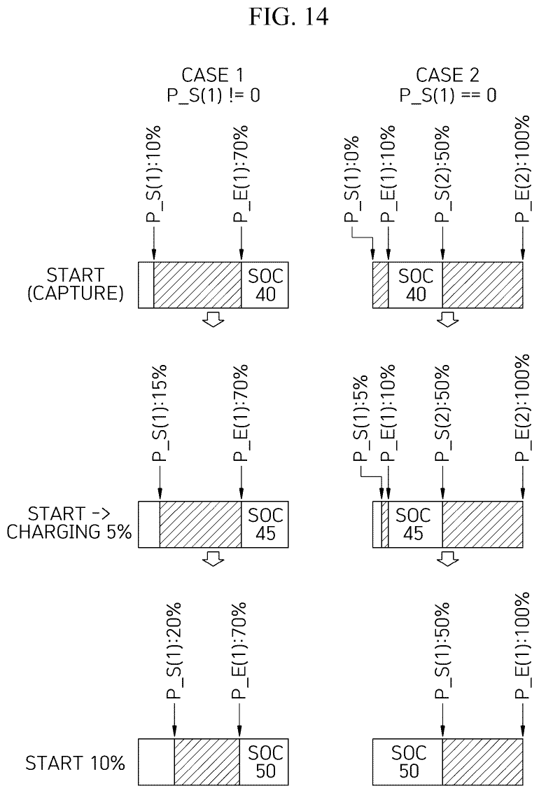

Hereinafter, with reference to FIGS. 14 to 17, a method of determining K_{OVP} in the battery model generator 110 of the LFP battery model generation apparatus 100 according to embodiments of the present disclosure will be described.

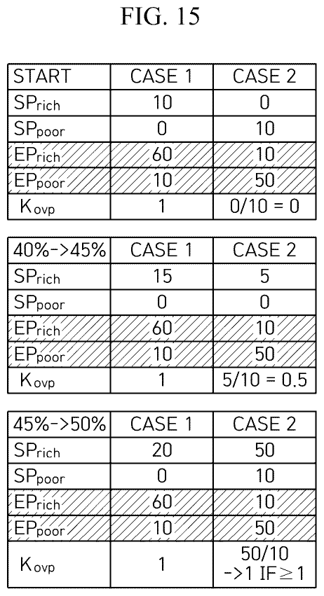

FIGS. 14 and 15 are diagrams for explaining examples in which the battery model generator of the LFP battery model generation apparatus according to embodiments of the present disclosure generates a battery model based on a state of lithium in the positive electrode active material of the LFP battery, the state being recorded by the lithium state recorder during charging of the LFP battery.

Referring to FIGS. 14 and 15, the battery model generator 110 may generate a battery model of the LFP battery 1 by classifying, when charging the LFP battery 1, the state of the lithium distribution into a first circumstance in which lithium ions are not distributed in the peripheral portion of the positive electrode active material of the LFP battery 1, and a second circumstance in which lithium ions are distributed in the peripheral portion of the positive electrode active material of the LFP battery 1.

The first circumstance may correspond to the circumstance in which lithium ions have been extracted during a previous charging process, resulting in the absence of lithium ions in the peripheral portion of the positive electrode active material. The second circumstance may correspond to the circumstance in which lithium ions have entered during a previous discharging process, resulting in lithium ions being accumulated in the peripheral portion of the positive electrode active material. The aforementioned lithium distribution may be maintained regardless of whether a rest period exists between a previous state and a current state.

As shown in FIG. 14, in the first circumstance, when charging is performed from an SOC of 40% to an SOC of 50% through an SOC of 45%, starting from a state in which lithium ions are absent in the peripheral portion of the positive electrode active material, lithium ions in the inner portion are required to pass through a portion in the poor phase to exit, resulting in high internal resistance.

Here, when, during charging of the LFP battery, at the moment when the charging begins, a starting point of the rich phase of lithium from the peripheral portion in the positive electrode active material of the LFP battery is designated as SP_{rich}, a first ending point of the rich phase is designated as EP_{rich}, a first ending point of the poor phase is designated as EPₚₒₒᵣ, and EP_{rich} is smaller than EPₚₒₒᵣ, a correction value K_{OVP} reflecting the state of lithium in the positive electrode active material may be determined by the following equation.

$${K}_{ovp} = \frac{{SP}_{rich}}{{EP}_{rich}} \qquad [ Equation 2 ]$$

Furthermore, when EP_{rich} is greater than or equal to EPₚₒₒᵣ, the correction value K_{OVP} reflecting the state of lithium in the positive electrode active material may be set to 1. In this circumstance, SP_{rich} may be a value that changes in real time depending on the current, and EP_{rich} and EPₚₒₒᵣ may be determined when the current changes from zero or when the present direction of the current changes.

In the first circumstance of FIG. 15, when the SOC is 40%, 45%, and 50%, EP_{rich} is greater than EPₚₒₒᵣ in all circumstances, and thus, K_{OVP} becomes 1. In other words, because the peripheral region is in a poor phase during charging, lithium ions located in the inner portion are required to pass through the portion in the poor phase to exit, resulting in high internal resistance, and therefore, K_{OVP} becomes 1.

As shown in FIG. 14, in the second circumstance, when charging is performed from the SOC of 40% to the SOC of 50% through the SOC of 45%, starting from a state in which lithium ions are accumulated in the peripheral portion of the positive electrode active material, the lithium ions in the peripheral portion may be directly extracted from the peripheral portion. In this circumstance, internal resistance gradually increases until the lithium ions are completely extracted from the most peripheral portion in the rich phase.

In the second circumstance of FIG. 15, when the SOC is 40%, 45%, and 50%, EP_{rich} is smaller than EPₚₒₒᵣ in all circumstances, and thus K_{OVP} may be determined as SP_{rich}/EP_{rich}. In other words, when the SOC is 40%, Kₒᵥₚ becomes 0/10=0; when the SOC is 45%, Kₒᵥₚ becomes 5/10=0.5; and when the SOC is 50%, K_{OVP} becomes 50/10=5, but since 0≤K_{OVP}≤1, K_{OVP} becomes 1.

In FIG. 15, EP_{rich} and EPₚₒₒᵣ may be captured and determined at the beginning of charging, and may be maintained throughout the charging process because the direction of the current has not changed even once.

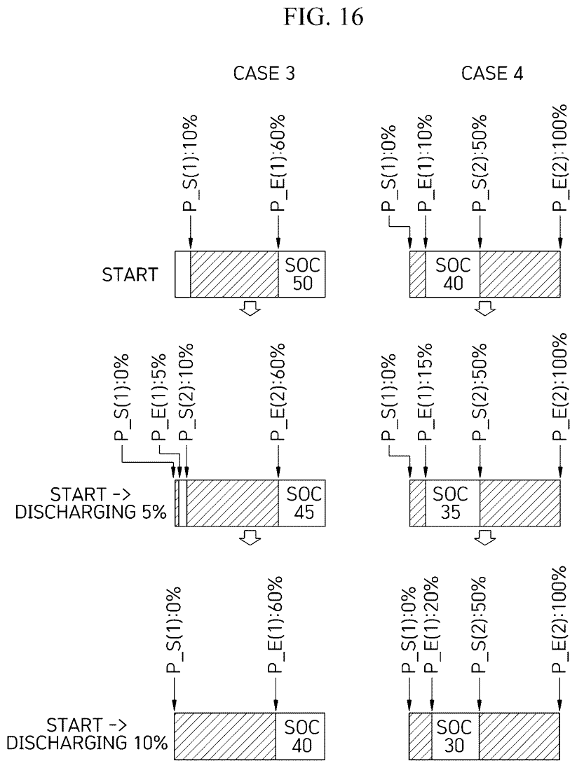

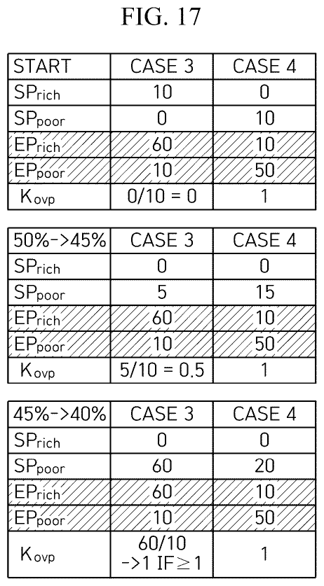

FIGS. 16 and 17 are diagrams for explaining examples in which the battery model generator of the LFP battery model generation apparatus according to embodiments of the present disclosure generates a battery model based on a state of lithium in the positive electrode active material of the LFP battery, the state being recorded by the lithium state recorder during discharging of the LFP battery.

Referring to FIGS. 16 and 17, the battery model generator 110 may generate a battery model of the LFP battery 1 by classifying, when discharging the LFP battery 1, the state of the lithium distribution into a third circumstance in which lithium ions are not distributed in the peripheral portion of the positive electrode active material of the LFP battery 1, and a fourth circumstance in which lithium ions are distributed in the peripheral portion of the positive electrode active material of the LFP battery 1.

The third circumstance may correspond to the circumstance in which lithium ions have been extracted during a previous charging process, resulting in the absence of lithium ion in the peripheral portion of the positive electrode active material. The fourth circumstance may correspond to the circumstance in which lithium ions have entered during a previous discharging process, resulting in lithium ions being accumulated in the peripheral portion of the positive electrode active material. The aforementioned lithium distribution may be maintained regardless of whether a rest period exists between a previous state and a current state.

As shown in FIG. 16, in the fourth circumstance, when discharging is performed from an SOC of 40% to an SOC of 30% through an SOC of 35%, starting from a state in which lithium ions are accumulated in the peripheral portion of the positive electrode active material, lithium ions positioned in the peripheral portion are required to move inward through a portion in the rich phase, resulting in relatively high internal resistance.

When, during discharging of the LFP battery, at the moment when discharging of the LFP battery begins, a first ending point of the rich phase of lithium from the peripheral portion in the positive electrode active material of the LFP battery is designated as EP_{rich}, a first starting point of the poor phase is designated as SPₚₒₒᵣ, a first ending point of the poor phase is designated as EPₚₒₒᵣ, and EPₚₒₒᵣ is smaller than EP_{rich}, the correction value K_{OVP} reflecting the state of lithium in the positive electrode active material may be determined by the following equation.

$${K}_{ovp} = \frac{{SP}_{poor}}{{EP}_{poor}} \qquad [ Equation 3 ]$$

Furthermore, in the circumstance where EPₚₒₒᵣ is greater than or equal to EP_{rich}, the correction value K_{OVP} reflecting the state of lithium in the positive electrode active material may be set to 1. In this circumstance, SPₚₒₒᵣ may be a value that changes in real time depending on the current, and EP_{rich} and EPₚₒₒᵣ may be determined when the current changes from zero or when the present direction of the current changes.

In the fourth circumstance of FIG. 17, when the SOC is 40%, 35%, and 30%, EPₚₒₒᵣ is greater than EP_{rich} in all circumstances, and thus K_{OVP} becomes 1. In other words, during discharging, because the peripheral portion is in a rich phase, lithium ions located in the peripheral portion are required to pass through the portion in the rich phase to enter, resulting in high internal resistance, and therefore, K_{OVP} becomes 1.

As shown in FIG. 16, in the third circumstance, when discharging is performed from an SOC of 50% to an SOC of 40% through an SOC of 45%, starting from a state in which lithium ions are absent in the peripheral portion of the positive electrode active material, lithium ions may enter from the outside of the positive electrode active material and immediately settle in place. Accordingly, resistance may gradually increase until the lithium ions fully occupy the most peripheral portion in the poor phase.

In the third circumstance of FIG. 17, when the SOC is 50%, 45%, and 40%, EPₚₒₒᵣ is smaller than EP_{rich} in all circumstances, and thus K_{OVP} may be determined as SPₚₒₒᵣ/EPₚₒₒᵣ. That is, when the SOC is 50%, K_{OVP} becomes 0/10=0; when the SOC is 45%, K_{OVP} becomes 5/10=0.5; and when the SOC is 40%, K_{OVP} becomes 60/10=6, but since 0≤K_{OVP}≤1, K_{OVP} becomes 1.

In FIG. 17, EP_{rich} and EPₚₒₒᵣ may be captured and determined at the beginning of charging, and may be maintained throughout the discharging process because the direction of the current has never changed even once.

According to embodiments of the present disclosure, the state of lithium in the positive electrode active material of the LFP battery 1 according to charging or discharging of the LFP battery 1 may be recorded, and a battery model of the LFP battery 1 may be generated based on the recorded state of lithium in the positive electrode active material. Accordingly, it is possible to record the state of lithium in the positive electrode active material that changes depending on the history of a previous charging or discharging path, define variation in internal resistance depending on n a current internal state of the positive electrode that reflects the history of the previous charging or discharging path, and ultimately apply the defined variation to the battery model.

According to embodiments of the present disclosure, a battery model that reflects the internal state of the positive electrode active material that varies depending on the history of the previous charging or discharging path may be generated. Hence, errors in the battery model may be reduced, and the accuracy may be improved, thereby reducing errors in the SOC and the SOH of the battery, which are calculated by the BMS.

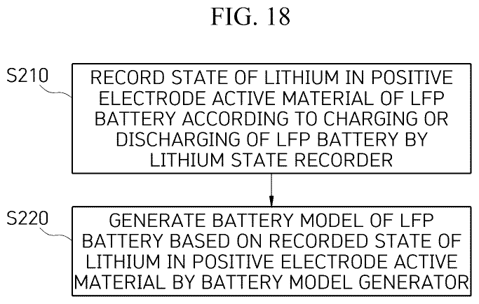

FIG. 18 is a flowchart for explaining a method of generating an LFP battery model according to embodiments of the present disclosure.

Referring to FIG. 18, the LFP battery model generation method according to embodiments of the present disclosure may include steps S210 and S220.

Step S210 includes recording, by the lithium state recorder, a state of lithium (Li) in a positive electrode active material of a lithium iron phosphate (LiFePO₄, LFP) battery according to charging or discharging of the LFP battery. In embodiments, step S210 may include recording a distribution state of lithium from a peripheral portion to a center in the positive electrode active material of the LFP battery, the distribution state varying depending on the charging or discharging of the LFP battery.

Step S220 is a battery model generation step of generating, by the battery model generator, a battery model of the LFP battery based on the recorded state of lithium in the positive electrode active material. In embodiments, step S220 may include generating the battery model by modeling the LFP battery using a plurality of capacitors and a plurality of resistors including an additional resistance component generated based on the state of lithium in the positive electrode active material.

In embodiments, step S220 may include generating the battery model of the LFP battery in a form in which the additional resistance component generated based on the state of lithium in the positive electrode active material is included in an equivalent circuit model (ECM).

In embodiments, step S220 may further include generating the battery model of the LFP battery by classifying, when charging the LFP battery, the state of the lithium distribution into a first circumstance in which the lithium is not distributed in the peripheral portion of the positive electrode active material of the LFP battery, and a second circumstance in which the lithium is distributed in the peripheral portion of the positive electrode active material of the LFP battery.

In other embodiments, step S220 may further include generating the battery model of the LFP battery by classifying, when discharging the LFP battery, the state of lithium distribution into a third circumstance in which lithium is not distributed in the peripheral portion of the positive electrode active material of the LFP battery, and a fourth circumstance in which lithium is distributed in the peripheral portion of the positive electrode active material of the LFP battery.

The herein-mentioned method of generating an LFP battery model according to embodiments of the present disclosure has been described with reference to the flowchart shown in the drawing. For brief explanation, the method has been illustrated and described as a series of blocks, but the present disclosure is not limited to the order of the blocks. In other words, some blocks may be executed simultaneously with other blocks or in a different order from those illustrated and described in this specification, and various diverges, flow paths, block sequences may also be implemented if they give the equivalent or similar results. In addition, to implement the method described in the specification, it is also possible not to demand all blocks.

In the description with reference to FIG. 18, each step may be further divided into additional steps, or some steps may be combined as fewer steps, based on implementation embodiments of the present disclosure. Furthermore, some steps may be omitted as needed, and a sequence of steps may be changed. In addition, despite other omitted description, the description provided with reference to FIGS. 1 to 17 may be applied to the description provided with reference to FIG. 18. Moreover, the description provided with reference to FIG. 18 may be applied to the description provided with reference to FIGS. 1 to 17.

Hereinafter, materials which may be used in a secondary battery according to an embodiment of the present disclosure are described.

A compound (e.g., a lithiated intercalation compound) capable of reversible intercalation and deintercalation of lithium may be used as a positive electrode active material. Specifically, one type or more selected among complex oxides of metal, selected among cobalt, manganese, nickel, and a combination of them, and lithium may be used as the positive electrode active material.

The complex oxide may be lithium transition metal complex oxide. A detailed example of the complex oxide may include lithium nickel-based oxide, lithium cobalt-based oxide, lithium manganese-based oxide, a lithium ferrous phosphate-based compound, cobalt-free nickel-manganese-based oxide, or a combination of them.

For example, a compound that is represented as one of the following chemical formulas may be used. LiₐA_{1-b}X_{b}O_{2-c}D_{c} (0.90≤a≤1.8, 0≤b≤0.5, 0≤c≤0.05); LiₐMn_{2-b}X_{b}O_{4-c}D_{c} (0.90≤a≤1.8, 0≤b≤0.5, 0≤c≤0.05); LiₐNi_{1-b-c}Co_{b}X_{c}O_{2-α}D_{α} (0.90≤a≤1.8, 0≤b≤0.5, 0≤c≤0.5, 0<α<2); LiₐNi_{1-b-c}Mn_{b}X_{c}O_{2-α}D_{α} (0.90≤a≤1.8, 0≤b≤0.5, 0≤c≤0.5, 0<α<2); LiₐNi_{b}Co_{c}L¹_{d}GₑO₂ (0.90≤a≤1.8, 0≤b≤0.9, 0≤c≤0.5, 0≤d≤0.5, 0≤e≤0.1); LiₐNiG_{b}O₂ (0.90≤a≤1.8, 0.001≤b≤0.1); LiₐCoG_{b}O₂ (0.90≤a≤1.8, 0.001≤b≤0.1); LiₐMn_{1-b}G_{b}O₂ (0.90≤a≤1.8, 0.001≤b≤0.1); LiₐMn₂G_{b}O₄ (0.90≤a≤1.8, 0.001≤b≤0.1); LiₐMn_{1-g}G_{g}PO₄ (0.90≤a≤1.8, 0≤g≤0.5); Li_{(3-f)}Fe₂(PO₄)₃ (0≤f≤2); and LiₐFePO₄ (0.90≤a≤1.8).

In the chemical formula, A may be Ni, Co, Mn, or a combination of them. X may be Al, Ni, Co, Mn, Cr, Fe, Mg, Sr, V, a rare earth element, or a combination of them; D may be O, F, S, P, or a combination of them. G may be Al, Cr, Mn, Fe, Mg, La, Ce, Sr, V, or a combination of them. L¹ may be Mn, Al, or a combination of them.

A positive electrode for a lithium secondary battery may include a current collector and a positive electrode active material layer formed on the current collector. The positive electrode active material layer may include the positive electrode active material, and may further include a binder and/or a conductive material.

Content of the positive electrode active material may be 90 wt. % to 99.5 wt. % with respect to the positive electrode active material layer 100 wt. %. Content of the binder and the conductive material may be 0.5 wt. % to 5 wt. % with respect to the positive electrode active material layer 100 wt. %.

Al may be used as the current collector, but the present disclosure may not be limited thereto.

A negative electrode active material may include a material capable of reversibly Intercalation/de-intercalation with respect to lithium ions, lithium metal, an alloy of lithium metal, a material capable of doping and dedoping with respect to lithium, or transition metal oxide.

The material capable of reversibly Intercalation/de-intercalation with respect to lithium ions may include a carbon-based negative electrode active material, for example, crystalline carbon, amorphous carbon, or a combination of them. An example of the crystalline carbon may include graphite, such as natural graphite or synthetic graphite. Examples of the amorphous carbon may include soft or hard carbon, mesophase pitch carbide, and fired coke.

An Si-based negative electrode active material or an Sn-based negative electrode active material may be used as the material capable of doping and dedoping with respect to lithium. The Si-based negative electrode active material may be silicon, a silicon-carbon composite, SiOₓ (0<x<2), a Si-based alloy, or a combination of them.

The silicon-carbon composite may be a composite of silicon and amorphous carbon. According to an implementation example, the silicon-carbon composite may include silicon particles, and may have a form in which amorphous carbon has been coated on surfaces of silicon particles.

The silicon-carbon composite may further include crystalline carbon. For example, the silicon-carbon composite may include a core including crystalline carbon and silicon particles, and an amorphous carbon coating layer disposed on a surface of the core.

A negative electrode for a lithium secondary battery may include a current collector and a negative electrode active material layer disposed on the current collector. The negative electrode active material layer may include the negative electrode active material, and may further include a binder and/or a conductive material.

For example the negative electrode active material layer may include the negative electrode active material of 90 wt. % to 99 wt. %, the binder of 0.5 wt. % to 5 wt. %, and the conductive material of 0 wt. % to 5 wt. %.

A nonaqueous-based binder, an aqueous-based binder, a dry binder, or a combination of them may be used as the binder. If the aqueous-based binder is used as a binder for the negative electrode, the binder for the negative electrode may further include a cellulose-series compound capable of assigning viscosity.

One selected among nickel foil, stainless steel foil, titanium foil, nickel foam, copper foam, a polymer base on which a conductive metal has been coated, and a combination of them may be used as a current collector for the negative electrode.

An electrolyte for a lithium secondary battery may include a nonaqueous organic solvent and lithium salts.

The nonaqueous organic solvent may play a role as a medium through which ions that are involved in an electrochemical reaction of a battery can move.

The nonaqueous organic solvent may be a carbonate-based, ester-based, ether-based, ketone-based, or alcohol-based solvent, an aprotic solvent, or a combination of them. The carbonate-based, ester-based, ether-based, ketone-based, or alcohol-based solvent, or the aprotic solvent may be used solely, or two types or more of them may be mixed and used as the nonaqueous organic solvent.

Furthermore, if the carbonate-based solvent is used, annular carbonate and chain carbonate may be mixed and used.

A separator may be present between the positive electrode and the negative electrode depending on the type of lithium secondary battery. Polyethylene, polypropylene, and polyvinylidene fluoride, or a multi-layer having two or more layers of them may be used as the separator.

The separator may include a porous base, and a coating layer including an organic matter, an inorganic matter, or a combination of them that is disposed on one or both sides of the porous base.

The organic matter may include a polyvinylidene fluoride-based heavy antibody or (meth)acrylic polymer.

The inorganic matter may include inorganic particles selected among Al₂O₃, SiO₂, TiO₂, SnO₂, CeO₂, MgO, NiO, Cao, GaO, ZnO, ZrO₂, Y₂O₃, SrTiO₃, BaTiO₃, Mg(OH)₂, boehmite, and a combination of them, but the present disclosure is not limited thereto.

The organic matter and the inorganic matter may have a form in which the organic matter and the inorganic matter have been mixed in one coating layer or a form in which a coating layer including the organic matter and a coating layer including the inorganic matter have been stacked

Although the present disclosure has been described herein in connection with the limited embodiments and drawings, the present disclosure is not limited to the embodiments. A person having ordinary knowledge in the art to which the present disclosure pertains may modify and change the present disclosure within the technical spirit of the present disclosure and the equivalent range of the following claims.

What is claimed is:

1. An apparatus for generating a lithium iron phosphate (LiFePO₄, LFP) battery model, the apparatus comprising:
a lithium state recorder configured to record a state of lithium (Li) in a positive electrode active material of an LFP battery according to charging or discharging of the LFP battery; and
a battery model generator configured to generate a battery model of the LFP battery based on the recorded state of the Li in the positive electrode active material,
wherein the battery model generator generates a battery model by modeling the LFP battery using a capacitor and a plurality of resistors including an additional resistance component generated based on the state of the Li in the positive electrode active material.

2. The apparatus as claimed in claim 1, wherein the Li state recorder records a distribution state of the Li from a peripheral portion to a center in the positive electrode active material of the LFP battery, the distribution state varying depending on the charging or discharging of the LFP battery.

3. The apparatus as claimed in claim 2, wherein the battery model generator generates the battery model of the LFP battery in a form in which the additional resistance component generated based on the state of the Li in the positive electrode active material is included in an equivalent circuit model (ECM).

4. The apparatus as claimed in claim 3, wherein the battery model generator generates the battery model of the LFP battery by classifying, when charging the LFP battery, the state of the Li distribution into a first circumstance in which the Li is not distributed in the peripheral portion of the positive electrode active material of the LFP battery, and a second circumstance in which the Li is distributed in the peripheral portion of the positive electrode active material of the LFP battery.

5. The apparatus as claimed in claim 3, wherein the battery model generator generates the battery model of the LFP battery by classifying, when discharging the LFP battery, the state of the Li distribution into a third circumstance in which the Li is not distributed in the peripheral portion of the positive electrode active material of the LFP battery, and a fourth circumstance in which the Li is distributed in the peripheral portion of the positive electrode active material of the LFP battery.

6. The apparatus as claimed in claim 3, wherein when the additional resistance component measured in a circumstance where a path-dependent effect of the positive electrode active material is greatest is designated as R_{ovp_max}, and a correction value reflecting the state of the Li in the positive electrode active material is designated as Kₒᵥₚ, an additional resistance component Rove generated based on the state of the Li in the positive electrode active material is determined by a following equation:
$${R}_{ovp} = {K}_{ovp} * {R}_{ovp \_ max} .$$

7. The apparatus as claimed in claim 6, wherein when, during charging of the LFP battery, at a moment when the charging begins, a starting point of a rich phase of the Li from the peripheral portion in the positive electrode active material of the LFP battery is designated as SP_{rich}, a first ending point of the rich phase is designated as EP_{rich}, a first ending point of a poor phase is designated as EPₚₒₒᵣ, and EP_{rich} is smaller than EPₚₒₒᵣ, a correction value K_{OVP} reflecting the state of the Li in the positive electrode active material is determined by a following equation:
$${K}_{ovp} = \frac{{SP}_{rich}}{{EP}_{rich}} .$$

8. The apparatus as claimed in claim 7, wherein in a circumstance where the EP_{rich} is greater than or equal to EPₚₒₒᵣ, the correction value K_{OVP} reflecting the state of the Li in the positive electrode active material is set to 1.

9. The apparatus as claimed in claim 4, wherein when, during discharging of the LFP battery, at a moment when the discharging begins, a first ending point of a rich phase of the Li from the peripheral portion in the positive electrode active material of the LFP battery is designated as EP_{rich}, a first starting point of a poor phase is designated as SPₚₒₒᵣ, a first ending point of the poor phase is designated as EPₚₒₒᵣ, and EPₚₒₒᵣ is smaller than EP_{rich}, a correction value K_{OVP} reflecting the state of the Li in the positive electrode active material is determined by a following equation:
$${K}_{ovp} = \frac{{SP}_{poor}}{{EP}_{poor}} .$$

10. The apparatus as claimed in claim 9, wherein in a circumstance where the EPₚₒₒᵣ is greater than or equal to EP_{rich}, the correction value K_{OVP} reflecting the state of the Li in the positive electrode active material is set to 1.

11. A method of generating a lithium iron phosphate (LiFePO₄, LFP) battery model, the method comprising:
a lithium state recording operation of recording, by a lithium state recorder, a state of lithium (Li) in a positive electrode active material of an LFP battery according to charging or discharging of the LFP battery; and
a battery model generation operation of generating, by a battery model generator, a battery model of the LFP battery based on the recorded state of the Li in the positive electrode active material,
wherein the battery model generation operation comprises generating the battery model by modeling the LFP battery using a capacitor and a plurality of resistors including an additional resistance component generated based on the state of the Li in the positive electrode active material.

12. The method as claimed in claim 11, wherein the Li state recording operation comprises recording a distribution state of the Li from a peripheral portion to a center in the positive electrode active material of the LFP battery, the distribution state varying depending on the charging or discharging of the LFP battery.

13. The method as claimed in claim 12, wherein the battery model generation operation comprises generating the battery model of the LFP battery in a form in which the additional resistance component generated based on the state of the Li in the positive electrode active material is included in an equivalent circuit model (ECM).

14. The method as claimed in claim 13, wherein the battery model generation operation comprises generating the battery model of the LFP battery by classifying, when charging the LFP battery, the state of the Li distribution into a first circumstance in which the Li is not distributed in the peripheral portion of the positive electrode active material of the LFP battery, and a second circumstance in which the Li is distributed in the peripheral portion of the positive electrode active material of the LFP battery.

15. The method as claimed in claim 13, wherein the battery model generation operation further comprises generating the battery model of the LFP battery by classifying, when discharging the LFP battery, the state of the Li distribution into a third circumstance in which the Li is not distributed in the peripheral portion of the positive electrode active material of the LFP battery, and a fourth circumstance in which the Li is distributed in the peripheral portion of the positive electrode active material of the LFP battery.

16. The method as claimed in claim 13, wherein the battery model generation operation comprises determining an additional resistance component R_{OVP} generated based on the state of the Li in the positive electrode active material by a following equation, when the additional resistance component measured in a circumstance where a path-dependent effect of the positive electrode active material is greatest is designated as R_{ovp_max}, and a correction value reflecting the state of the Li in the positive electrode active material is designated as Kₒᵥₚ:
$${R}_{ovp} = {K}_{ovp} * {R}_{ovp \_ max} .$$

17. The method as claimed in claim 16, wherein the battery model generation operation further comprises determining the correction value K_{OVP} reflecting the state of the Li in the positive electrode active material by a following equation when, during charging of the LFP battery, at a moment when the charging begins, a starting point of a rich phase of the Li from the peripheral portion in the positive electrode active material of the LFP battery is designated as SP_{rich}, a first ending point of the rich phase is designated as EP_{rich}, a first ending point of a poor phase is designated as EPₚₒₒᵣ, and EP_{rich} is smaller than EPₚₒₒᵣ:
$${K}_{ovp} = \frac{{SP}_{rich}}{{EP}_{rich}} .$$

18. The method as claimed in claim 17, wherein the battery model generation operation further comprises setting the correction value Kₒᵥₚ reflecting the state of the Li in the positive electrode active material to 1 in a circumstance where the EP_{rich} is greater than or equal to EPₚₒₒᵣ.

19. The method as claimed in claim 16, wherein the battery model generation operation further comprises detemining a correction value K_{OVP} reflecting the state of the Li in the positive electrode active material by a following equation when, during discharging of the LFP battery, at a moment when the discharging begins, a first ending point of a rich phase of the Li from the peripheral portion in the positive electrode active material of the LFP battery is designated as EP_{rich}, a first starting point of a poor phase is designated as SPₚₒₒᵣ, a first ending point of the poor phase is designated as EPₚₒₒᵣ, and EPₚₒₒᵣ is smaller than EP_{rich}:
$${K}_{ovp} = \frac{{SP}_{poor}}{{EP}_{poor}} .$$

20. The method as claimed in claim 19, wherein the battery model generation operation further comprises setting the correction value K_{OVP} reflecting the state of the Li in the positive electrode active material to 1 in a circumstance where the EPₚₒₒᵣ is greater than or equal to EP_{rich}.
